(19) United States
(12) Patent Application Publication
(10) Pub. No.: US 2026/0190841 A1
(43) Pub. Date: Jul. 2, 2026

(54) DISPLAY DEVICE

(71) Applicant: LG Display Co., Ltd., Seoul (KR)

(72) Inventors: Kwangmin Lee, Chilgok-gun (KR); Keumyoung Oh, Gumi-si (KR)

(21) Appl. No.: 19/224,146

(22) Filed: May 30, 2025

(30) Foreign Application Priority Data
Dec. 31, 2024 (KR) 10-2024-0201811

(51) Int. Cl. H10K 59/80; B60K 37/20; G02F 1/1335; H10K 102/00

(52) U.S. Cl. CPC H10K 59/8793; B60K 37/20; G02F 1/133512; G02F 1/133528; H10K 59/8722; H10K 59/8792; H10K 2102/311

(57) ABSTRACT

A display device includes a display panel including a general area having a flat surface and a bent area having a bent surface; and an optical adjustment layer disposed on the display panel, wherein the optical adjustment layer includes a first area corresponding to the general area and a second area corresponding to the bent area, and wherein an angle of a light transmission axis of the optical adjustment layer in the first area is different from an angle of a light transmission axis of the optical adjustment layer in the second area. The display device can help prevent a displayed image output from the display device from being reflected on and from a windshield of a vehicle. Thus, the vehicle driver can drive safely without the reflected image on the windshield interfering with the view of the driver.

### CROSS-REFERENCE TO RELATED APPLICATION

Pursuant to 35 U.S.C. § 119(a), this application claims the benefit of an earlier filing date and right of priority to Korean Patent Application No. 10-2024-0201811 filed on Dec. 31, 2024 in the Korean Intellectual Property Office, the contents of which are incorporated by reference herein in their entirety.

### TECHNICAL FIELD

The present disclosure relates to a display device applied to a vehicle.

### BACKGROUND

In recent years, the uses of display devices have become more diverse, their thickness has become thinner, and their weight has become lighter, the scope of their use is expanding, and the display devices are used in various fields. Thus, the demand for display devices that provide high-quality images is increasing.

Recently, a vehicle display device mounted inside a vehicle to provide an image to a user sitting in the driver's seat or passenger seat has become popular.

### SUMMARY

A display device according to one implementation of the present disclosure includes: a display panel including a general area having a flat surface and a bent area having a bent surface; and an optical adjustment layer disposed on the display panel, wherein the optical adjustment layer includes a first area corresponding to the general area and a second area corresponding to the bent area, wherein an angle of a light transmission axis of the optical adjustment layer in the first area is different from an angle of a light transmission axis of the optical adjustment layer in the second area.

### BRIEF DESCRIPTION OF DRAWINGS

FIG. 1 is a diagram schematically illustrating a vehicle on which a display device according to an implementation of the present disclosure is mounted.

FIG. 2 is a diagram schematically illustrating an outer appearance of a display device according to an implementation of the present disclosure.

FIG. 3 is an exploded perspective view illustrating an example of a display device according to an implementation of the present disclosure.

FIG. 4 is an exploded perspective view illustrating an exploded display panel according to an implementation of the present disclosure.

FIG. 5 is a diagram illustrating a cutting line along which a display module according to an implementation of the present disclosure is cut

FIG. 6 is a diagram illustrating a display module as cut along a cutting line according to an implementation of the present disclosure.

FIG. 7 is a diagram illustrating a display device and an incident surface of a windshield according to an implementation of the present disclosure.

FIG. 8 is a diagram illustrating a relationship between a transmission axis and an incident surface of a polarizing layer, a P wave, and an S wave according to an implementation of the present disclosure.

FIG. 9 is a diagram illustrating an example in which a displayed image is reflected on a windshield according to the presence of the P waves and the S wave vibrating along a transmission axis of a polarization layer when a display device according to an implementation of the present disclosure is bent.

FIG. 10 is a diagram illustrating an example in which a displayed image is not reflected on a windshield according to the presence of only a P wave vibrating along a transmission axis of a polarization layer when a display device according to an implementation of the present disclosure is bent.

### DETAILED DESCRIPTIONS

A vehicle display device includes a display area (Active Area; hereinafter referred to as AA) that displays a screen and a non-display area (Non-active Area hereinafter referred to as NA) formed along an outer edge of the display area. The non-display area is referred to as a bezel area. When the bezel area is thick, the user's gaze can be distracted by the larger bezel area. By contrast, when the bezel area is thin, the user's gaze is more focused on the screen of the display area, which may increase immersion.

However, in a vehicle display device, a displayed image output from the display device is often reflected on and from the windshield to a viewer. This can interfere with a view of the vehicle driver.

Accordingly, implementations of the present disclosure provide a display device that can help prevent a displayed image output from the display device from being reflected on and from a windshield to a viewer.

In some scenarios, implementations of the present disclosure provide a display device in which a light transmission axis of a polarizing layer is oriented such that, in a state in which a display device mounted on a vehicle has been bent to display an image, the displayed image output from the display device is prevented from being reflected on and from a windshield to a viewer.

Purposes according to the present disclosure are not limited to the above-mentioned purpose. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims or combinations thereof.

According to an implementation of the present disclosure, the angle of the transmission axis of the polarization layer in the general area (front surface or flat surface) of the display device mounted on the vehicle and the angle of the transmission axis of the polarization layer in the bent area (bent surface) of the display device may be set to be different from each other, thereby preventing the displayed image from being reflected on and from the windshield to the viewer.

In addition, according to an implementation of the present disclosure, the displayed image from the display device mounted on the vehicle is not reflected on and from the windshield, such that the vehicle driver can drive safely without the reflected image on the windshield interfering with the view of the driver.

In addition, according to an implementation of the present disclosure, in the display device mounted on the vehicle, a pixel shielding film is formed on each of the front surface and the bent surface such that the light beams respectively emitted from both the left and right sides and the middle of the display device are emitted in an exactly frontward direction, and thus the displayed image portions respectively emitted from both the left and right sides and the middle thereof are visually recognized at the same brightness, thereby improving image quality.

In addition, according to an implementation of the present disclosure, the image quality of the display panel may be improved to prevent deterioration of the lifespan of the display panel.

In addition, according to an implementation of the present disclosure, as the image quality of the display panel is improved, the display panel operates without failure, thereby providing a long-life low-power display device operating in a reliable manner.

The effects of the present disclosure are not limited to the effects as mentioned above, and other effects not mentioned above will be clearly understood by those skilled in the art from following descriptions.

In addition to the above-described effects, the specific effects of the present disclosure are described below while describing specific details for implementing the implementations of the present disclosure.

Advantages and features of the present disclosure, and a method of achieving the advantages and features will become apparent with reference to implementations described later in detail together with the accompanying drawings. However, the present disclosure is not limited to the implementations as disclosed under, but may be implemented in various different forms. Thus, these implementations are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various implementations are illustrated and described further below. It will be understood that the description herein is not intended to limit the claims to the specific implementations described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating implementations of the present disclosure are illustrative, and the present disclosure is not limited thereto.

The terminology used herein is directed to the purpose of describing particular implementations only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to, or coupled to the other element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present.

Further, as used herein, when a layer, film, area, plate, or the like is disposed “on” or “on top” of another layer, film, area, plate, or the like, the former may directly contact the latter or still another layer, film, area, plate, or the like may be disposed between the former and the latter. As used herein, when a layer, film, area, plate, or the like is directly disposed “on” or “on top” of another layer, film, area, plate, or the like, the former directly contacts the latter and still another layer, film, area, plate, or the like is not disposed between the former and the latter. Further, as used herein, when a layer, film, area, plate, or the like is disposed “beneath” or “under” another layer, film, area, plate, or the like, the former may directly contact the latter or still another layer, film, area, plate, or the like may be disposed between the former and the latter. As used herein, when a layer, film, area, plate, or the like is directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain implementation may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an implementation may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various implementations of the present disclosure may be partially or entirely combined with each other, and may be technically associated with each other or operate with each other. The implementations may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “implementations,” “examples,” “aspects, and the like should not be construed such that any aspect or design as described is superior to or advantageous over other aspects or designs.

Further, the term ‘or’ means ‘inclusive or’ rather than ‘exclusive or'. That is, unless otherwise stated or clear from the context, the expression that 'x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating implementations.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B through another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

As used herein, the term “display device” may include, in a narrow sense, a display device including a liquid crystal module (LCM), an organic light-emitting diode (OLED) module, or a quantum dot (QD) module including a display panel and a driver for driving the display panel. Moreover, the display device may include, in a broad sense, a laptop computer, a television, a computer monitor, an automotive device or an equipment display for a vehicle, a set electronic device, a set device or a set device including a complete product or a final product including the LCM, the OLED module, or the QD module.

Therefore, the display device in accordance with the present disclosure may include, in the narrow sense, a display device itself including, for example, the LCM, the OLED module, QD module, etc., and may include, in a broad sense, the set device as an application product or an end-user device including a complete product or a final product including the LCM, the OLED module, or the QD module.

Moreover, in some cases, the LCM, OLED module, or QD module composed of the display panel and the driver may be expressed as “display device” in a narrow sense. The electronic device as a complete product including the LCM, OLED module or QD module may be expressed as “set” device” in a broad sense. For example, the display device in the narrow sense may include a display panel such as a liquid crystal panel, an organic light-emitting display panel, or a quantum dot display panel, and a source PCB as a controller for driving the display panel. The set device in the broad sense may include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel may be of any type of the display panels such as a liquid crystal display panel, an organic light emitting diode (OLED) display panel, a quantum dot (QD) display panel, and an electroluminescent display panel, etc. The display panel used in the disclosure may not be limited to a specific display panel including a flexible substrate for the OLED display panel and an underlying back plate support structure and having a bendable bezel. Moreover, the display panel used in the display device according to an implementation of the present disclosure is not limited to a shape or a size of the display panel.

Hereinafter, implementations of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure may work functionally.

Hereinafter, a display device according to an implementation of the present disclosure will be described with reference to the drawings. More specifically, a display device that prevents a displayed image output from the display device from being reflected from a windshield to a viewer will be described with reference to the drawings.

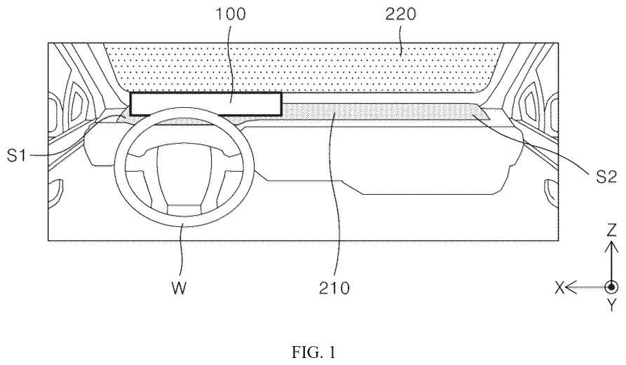

FIG. 1 is a diagram schematically showing a vehicle on which a display device according to an implementation of the present disclosure is mounted.

A frontward and upward direction defined in the present disclosure refers to a Z-axis direction, and a backward and downward direction refers to a −Z-axis direction.

Referring to FIG. 1, a vehicle on which a display device according to some implementations of the present disclosure is mounted includes a dashboard 210 adjacent to a bottom of a front glass 220 (or a windshield) and a display device 100 disposed on the dashboard 210.

The display device 100 may be disposed between one edge S1 and the other edge S2 of the dashboard 210. FIG. 1 illustrates that the display device 100 is disposed between a steering wheel W and the front glass 220. However, implementations of the present disclosure are not limited thereto. Furthermore, the display device 100 may extend from one edge S1 to the other edge S2 of the dashboard 210. In this case, not only the driver but also the passenger in the passenger seat may view the image displayed on the display device 100.

The display device 100 may display an image in a general image mode and a multi-view mode.

The display device 100 displays one image the general image mode as a general display device does. In this case, the display device 100 may display one image in a wide viewing angle range so that all viewers located in front of the device 100 may comfortably view the image. Thus, both the driver and the passenger in the passenger seat may view one image displayed on the display device 100.

The display device 100 may display a first image in a first direction and a second image in a second direction different from the first direction in the multi-view mode. The first direction may be a direction toward a position on top of the driver's gaze and may be a direction toward a position in front of and on top of the display device 100. The second direction may be the driver's gaze direction and may be a direction toward a position in front of and under the display device 100.

The front glass 220 is present in the first direction. Thus, the first image is directed to the front glass 220 and is thus displayed to the driver as a virtual image. Thus, a head up display (HUD) is realized. Furthermore, the driver is present in the second direction. Thus, the second image is visible to the driver in a real manner, that is, directly.

As discussed above, according to an implementation of the present disclosure, the display device 100 that displays the first image in the first direction toward the front windshield 200 and displays the second image in the second direction toward the driver in the multi-view mode is disposed on the dashboard 210 of the vehicle. As a result, according to an implementation of the present disclosure, the driver may obtain driving information from a plurality of images because the driver may view the first image in the head-up display manner and at the same time, may directly view the second image. This may increase the driver's driving convenience.

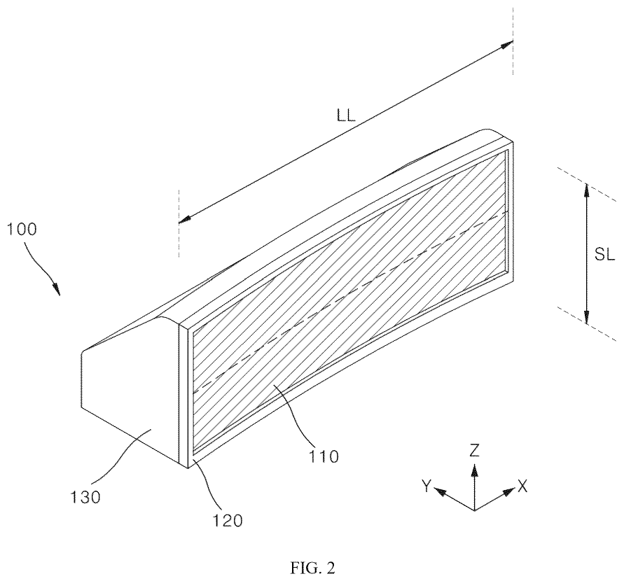

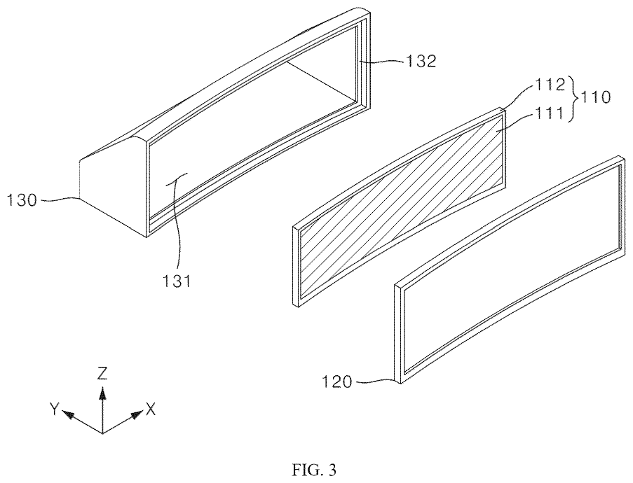

FIG. 2 is a drawing schematically showing an outer appearance of a vehicle display device according to an implementation of the present disclosure, and FIG. 3 is an exploded perspective view showing the vehicle display device according to an implementation of the present disclosure.

Referring to FIG. 2 and FIG. 3, the display device 100 according to an implementation of the present disclosure may have a long side and a short side.

A short side length SL of the display device 100 may be smaller than a short side length of the dashboard 210. A long side length LL of the display device 100 may be smaller than a length from one edge S1 to the other edge S2 of the dashboard 210, as shown in FIG. 1.

The display device 100 according to an implementation of the present disclosure may include a display module 110, a front cover 120, and a housing 130.

The display module 110 may include a display panel 111 and a rear cover 112. The display panel 111 may be mounted on the rear cover 112. The display panel 111 may have a front cover 120 as a front portion, and a rear cover 112 as a rear portion.

The display module 110 may be a liquid crystal display module or an organic light-emitting display module. The display module 110 directly displays an image using a liquid crystal display panel or an organic light-emitting display panel. Thus, the display module 110 has excellent outdoor visibility, viewing angle, resolution, and luminance, compared to an image projection scheme, and thus has high information transmission ability, and minimized change in visibility depending on the external environment (weather, or when wipers move).

The display module 110 may include the display panel 111, a guide frame (not shown) supporting the display panel 111, a lower cover (not shown) that stores therein a backlight unit and supports the guide frame, and an upper case (not shown) covering a front edge of the display panel 111 and a side surface of the lower cover. When the display module 110 is implemented as the liquid crystal display module, the display module may further include the backlight unit (not shown) disposed on a lower surface of the display panel 111 so as to emit light thereto.

The display panel 111 may include one or more display areas. For example, the display panel 111 may include a first display area adjacent to the driver's seat, a second display area facing a separation area between the driver's seat and the passenger seat, and a third display area adjacent to the passenger seat.

The first display area may display at least one of measuring instrument data, around view data, and navigation data that are essential to the driver for safe vehicle driving. In particular, when the vehicle starts driving, the first display area may display the measuring instrument data.

The second display area may display any one of around view data, navigation data, and media data.

The third display area may display around view data, navigation data, and media data. In this regard, the media data corresponds to contents for the entertainment of the user riding on the passenger seat. For example, when the first display area displays the measuring instrument data, the third display area may display the media data.

Both opposing edges of the display panel 111 are bent backwards. In this regard, a reinforcing member that reinforces the bending of the display panel 111 may be disposed on an outside of the display panel 111. In this regard, the reinforcing member may include, for example, a micro coating layer. The micro coating layer may be referred to MCL.

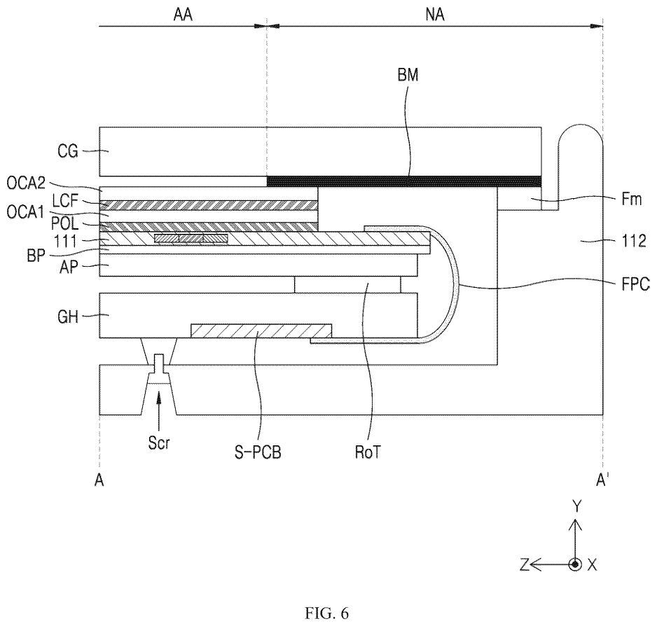

A polarizing layer (POL in FIG. 6) which will be described later may be attached to an upper surface of the display panel 111. The polarizing layer POL may have a transmission axis parallel to the long side of the display panel 111.

The display module 110 is stored in a storage space 131 of the housing 130 and displays an image based on image data supplied from a host system (not shown). The host system may supply the image data from at least one of a vehicle external camera (not shown), a driving image recording device (not shown), a navigation device (not shown), a portable terminal (not shown), an audio device (not shown), and a vehicle driving recording device (not shown) to the display module 110.

The front cover 120 may be provided in a form of a rectangular ring and may cover a front edge and a side surface of the display module 110.

The housing 130 may accommodate therein the display module 110. The housing 130 may be formed in a box shape having the storage space 131 and having an open front surface facing the driver's seat. A step-shaped module support surface 132 may be formed in a front edge of the storage space 131.

In an implementation of the present disclosure, an example in which the display device 100 is mounted on the dashboard 210 of the vehicle is described above. However, implementations of the present disclosure are not limited thereto. The display device 100 may be mounted at another location inside the vehicle.

In another example, the display panel 111 may also be disposed on the steering wheel W facing the driver's seat. In this case, the display panel 111 disposed on the dashboard 210 may be referred to as a first display panel unit, and the display panel 111 disposed on the steering wheel W may be referred to as a second display panel unit. In this regard, the second display panel unit may include one or more display areas. When the first display panel unit includes the first to third display areas, the second display panel unit may include a fourth display area.

Furthermore, since the second display panel unit faces the driver's seat, the user riding on the driver's seat may view the second display panel unit without moving his or her eyes to the left or right. Accordingly, like the first display area of the first display panel unit, the fourth display area of the second display panel unit may display at least one of the measuring instrument data, the around view data, and the navigation data that are essential to the driver for safe vehicle driving.

In this regard, the media data corresponds to contents for the user's enjoyment. The around view data corresponds to imaging data obtained from at least one of a rear camera, a front camera, and a side camera. The navigation data corresponds to data from a driving system (or GPS system). The measuring instrument data includes various observed or predicted information about various conditions of the vehicle. For example, the measuring instrument data may include at least one piece of information among the remaining amount of energy source of the vehicle, the vehicle's driving speed, coolant temperature, remaining engine oil amount, engine abnormality, whether a brake is activated, whether warning lights are activated, whether seat belts are worn, cumulative driving distance, possible driving distance, and fuel efficiency.

In another example, the display device 100 according to an implementation of the present disclosure may be disposed on a center fascia CP located under the dashboard 210 and between the driver's seat and the passenger seat. In this case, the display panel 111 disposed on the center fascia CP may be referred to as a third display panel unit. Accordingly, when the first display panel unit includes the first to third display areas, and the second display panel unit includes the fourth display area, the third display panel unit may include a fifth display area.

The fifth display area disposed on the center fascia CP may display a control setting window that provides a user control interface for setting surrounding environment data or vehicle status. In this regard, the user control interface may include a user interface for controlling the image data displayed on the first and second display panel units, and a user interface for displaying or controlling the air conditioning status inside the vehicle. The surrounding environment data includes various information about the vehicle. By way of example, the surrounding environment data may include at least one piece of information among the illuminance outside the vehicle, the illuminance inside the vehicle, whether the user is riding on the driver's seat of the vehicle, whether the user is riding on the passenger seat of the vehicle, whether user input is performed using the control setting window, whether a physical shock to the vehicle has occurred, autonomous driving status, the vehicle's driving direction, and the vehicle's driving speed.

However, this is only an example, and it is obvious that the display device 100 mounted on the vehicle may include at least one display panel unit disposed at various locations inside the vehicle. That is, at least one display panel unit of the display device 100 may further include a display panel unit disposed on the windshield, a display panel unit facing the rear seat, etc. in addition to the first, second, and third display panel units. Alternatively, at least one display panel unit of the display device 100 may include only the first display panel unit, or may include the first display panel unit and display panel units respectively disposed at various locations inside the vehicle.

In the display device 100 according to an implementation of the present disclosure, at least one display panel unit may provide a plurality of display areas. The plurality of display areas may include the first to third display areas disposed on the dashboard 210 of the vehicle, the fourth display area disposed on the steering wheel W of the vehicle, and the fifth display area disposed on the center fascia CP located under the dashboard 210. The fourth display area may display the measuring instrument data or the around view data, and the fifth display area may display the control setting window that provides the user control interface for setting the status of the vehicle.

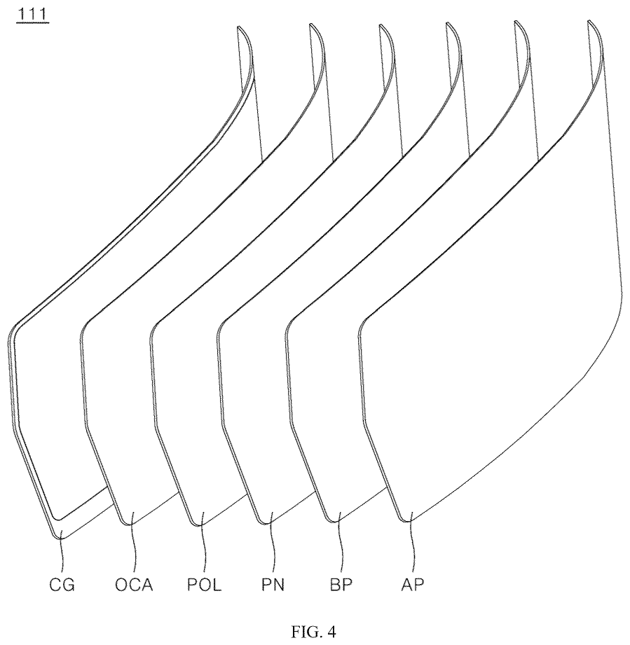

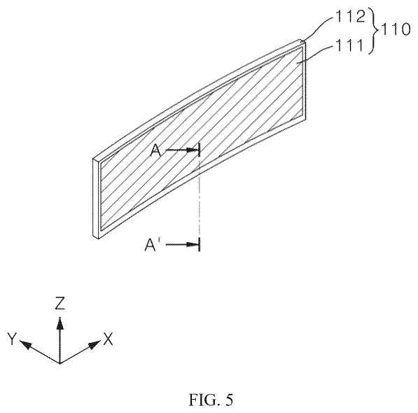

FIG. 4 is an exploded perspective view illustrating an exploded display panel according to an implementation of the present disclosure. FIG. 5 is a diagram illustrating a display panel and a rear cover corresponding thereto according to an implementation of the present disclosure.

Referring to FIG. 4, the display panel 111 according to an implementation of the present disclosure may include a metal plate AP, a back plate BP, a panel array PN, an optical adjustment layer POL, an optical adhesive layer OCA, and a cover member CG.

The back plate BP and the metal plate AP may support the display panel array PN. The back plate BP and the metal plate AP may be adhered to each other by a resin or an adhesive tape. For example, the back plate BP and the metal plate AP may be bonded to each other using an ultraviolet (UV) curable acrylic resin. However, implementations of the present disclosure are not limited thereto. Specifically, a resin disposed between the back plate BP and the metal plate AP may be implemented as a cured product of a resin obtained by performing a curing process of the curable resin. When the resin is used as an ultraviolet-curable resin, ultraviolet curing may be performed. The metal plate AP may be made of a metal material, for example, may be made of an aluminum (Aluminum) material.

The panel array PN may include a plurality of pixels. Each of the plurality of pixels may be composed of a plurality of sub-pixels. A plurality of light-emitting elements LD may be disposed in each of the plurality of sub-pixels SP. The plurality of light-emitting elements LD may be configured in a manner varying according to the type of the display device 100. For example, when the display device 100 is an inorganic light emitting display device, the light-emitting element may be a light-emitting diode (LED), a micro light-emitting diode (LED), or a mini light-emitting diode (LED). However, implementations of the present disclosure are not limited thereto.

A plurality of pixel driving circuits may be disposed in the display panel array PN. The plurality of pixel driving circuits may be configured for driving the light-emitting elements of the plurality of sub-pixels. For example, each of the plurality of pixel driving circuits may function as a driving transistor and a storage capacitor. For example, each of the plurality of pixel driving circuits may supply a control signal, a power, and a driving current to the light-emitting elements of the plurality of sub-pixels to control the light emitting operations of the plurality of light-emitting elements. For example, the pixel driving circuit may include a power line and a signal line for controlling light emission on/off and/or a light emission time of the light-emitting element. For example, the plurality of pixel driving circuits may be a driving driver manufactured using a metal-oxide-silicon field effect transistor (MOSFET) manufacturing process on a semiconductor substrate. However, implementations of the present disclosure are not limited thereto. The driving driver may drive the plurality of sub-pixels. For example, each of the plurality of pixel driving circuits may include a micro driver (μDriver). However, implementations of the present disclosure are not limited thereto. The micro driver may be implemented in a form of a chip. For example, each of the plurality of pixel driving circuits may include a driver chip. However, implementations of the present disclosure are not limited thereto.

The optical adjustment layer POL may include, for example, a polarization layer POL. Therefore, in an implementation of the present disclosure, the optical adjustment layer POL and the polarizing layer POL may be used together with each other. The polarizing layer POL prevents a decrease in a contrast ratio (CR) due to external light. In the display device 100 according to the present disclosure, the polarization layer POL that blocks external light incident from the outside may be positioned in a transmission path of light emitted through the display panel 111 in a driving mode in which the LED panel display an image, thereby improving the contrast ratio.

The optical adhesive layer OCA may be composed of at least one or more layers made of at least one or more materials of an OCA (Optical Clear Adhesive), an OCR (Optical Clear Resin), or a PSA (Pressure Sensitive Adhesive).

The optical adhesive layer OCA may have a thickness of, for example, 100 to 300 μm. When the optical adhesive layer OCA has a thickness of 100 μm or smaller, the adhesive strength thereof is weakened, so that it is difficult to modularize the cover member CG and the back plate BP into a module. When the optical adhesive layer OCA has a thickness of 300 μm or greater, it may be difficult for the display device 100 to be bent.

The cover member CG protects the display panel 111 from an external impact, and transmits light emitted from the display panel 111 therethrough so that an image displayed from the display panel 111 is visible to the outside. The cover member CG may be referred to as a cover glass or a cover window.

The cover member CG may be made of one of polymethyl methacrylate (PMMA), polycarbonate (PC), cyclo olefin polymer (COP), polyethylene terephthalate (PET), PI (polyimide), and PA (polyamide) having impact resistance and light transmittance. However, implementations of the present disclosure are not limited thereto.

FIG. 5 is a diagram illustrating a cutting line along which a display module according to an implementation of the present disclosure is cut, and FIG. 6 is a cross-sectional view illustrating a display module according to an implementation of the present disclosure along a cutting line A-A′.

Referring to FIG. 5, the display module 110 according to an implementation of the present disclosure may include the display panel 111 mounted on the rear cover 112.

Referring to FIG. 6, the display device according to an implementation of the present disclosure may include the optical adjustment layer POL disposed on the display panel 111 and the cover member CG disposed on the optical adjustment layer POL.

More specifically, in the display device, the optical adjustment layer POL may be disposed on the display panel 111, a first adhesive layer OCA1 may be disposed on the optical adjustment layer POL, a light control film LCF may be disposed on the first adhesive layer OCA1, a second adhesive layer OCA2 may be disposed on the light control film LCF, a black matrix BM may be disposed on the second adhesive layer OCA2, and the cover member CG may be disposed on the black matrix BM.

In addition, in the display device, the back plate BP may be disposed under the display panel 111, a metal plate (for example, an aluminum plate) AP may be disposed under the back plate BP, an adhesive tape (resin or tape: RoT) may be disposed under the metal plate AP, a guide holder GH may be disposed under the adhesive tape RoT, and a set frame SF may be disposed under the guide holder GH. The set frame SF may have the rear cover 112 extending upwardly from an outer portion thereof. The rear cover 112 may be disposed to be spaced apart from an outer periphery of the cover member CG by a predetermined spacing.

The display panel 111 may include a display area (active area) (hereinafter, referred to as AA) in which a plurality of sub-pixels are disposed and a non-display area (non-active area) (hereinafter, referred to as NA) surrounding the display area AA and formed along an outer edge of the display area AA.

Each of the first and second adhesive layers OCA1 and OCA2 may include, for example, an OCA (Optical Clear Adhesive).

The guide holder GH may be coupled and fixed to the rear cover 112 via a fastening means such as a screw Scr. The guide holder GH may include a source PCB (S-PCB) therein, and the source PCB may be electrically connected to the display panel 111 through a flexible printed circuit board FPC.

The black matrix BM may include a plurality of holes defined therein, and may be formed by filling a black pigment therein through the plurality of holes. The black matrix BM may be disposed on top of the display panel 111 and in a portion of the non-display area NA disposed between the display area AA and a portion of the rear cover 112 located at the outermost position of the non-display area NA. For example, the black matrix BM may be disposed between the second adhesive layer OCA2 and the cover member CG disposed on top of the display panel 111.

The black matrix BM includes black pigment (black ink or black resin). A concentration of the black pigment is distributed in a gradation manner through a separate manufacturing process. The black matrix BM may be disposed between the second adhesive layer OCA2 and the cover member CG. However, the black matrix BM is not limited to thereto. For example, the black matrix BM may be formed in a gradation printing manner on the cover member CG during a manufacturing process of the display module 110. The distribution in the gradation manner of the black matrix BM means that the concentration of the black pigment becomes increasingly denser as the BM extends in a direction from the display area AA to the rear cover 112. The black matrix BM may block light emission of the plurality of sub-pixels SP in the non-display area NA.

A density of the black pigment of the black matrix BM may increase as the black matrix extends in a direction from the display area AA to the rear cover 112 in the non-display area NA. That is, the black matrix BM may have a low density of the black pigment in an area adjacent to the display area AA and a higher density of the black pigment in an area adjacent to the rear cover 112.

Furthermore, the display module 110 may include an optical adjustment layer POL disposed on top of the display panel 111, the first adhesive layer OCA1 disposed on top of the optical adjustment layer POL, and a light control film LCF disposed on the first optical adhesive layer OCA1.

Furthermore, the display module 110 may further include the second adhesive layer OCA2 disposed on top of the light control film LCF, the black matrix BM disposed on top of the second optical adhesive layer OCA2, and the cover member CG disposed on top of the black matrix BM.

The rear cover 112 may extend from the outer portion of the set frame SF in an upward direction. The set frame SF may have a flat bottom in the display area AA and the non-display area NA, and may extend upwardly from an end of the non-display area NA to form the rear cover 112.

The rear cover 112 may have a stepped portion on which an outer edge of the cover member CG is seated. Accordingly, the outer portion of the cover member CG and the end portion of the black matrix BM may be seated on the stepped portion of the rear cover 112.

The stepped portion of the rear cover 112 and the end of the black matrix BM may be adhered to each other by an adhesive. The adhesive may bond the stepped portion of the rear cover 112 and the end portion of the black matrix BM to each other in a tape or glue manner.

The adhesive may include a foam member Fm. The stepped portion of the rear cover 112 and the end of the black matrix BM may be adhered to each other by the foam member Fm. The foam member may be formed in a form including a foam tape or a foam pad and may include a tape having a shock absorbing function or a double-sided tape having conductivity.

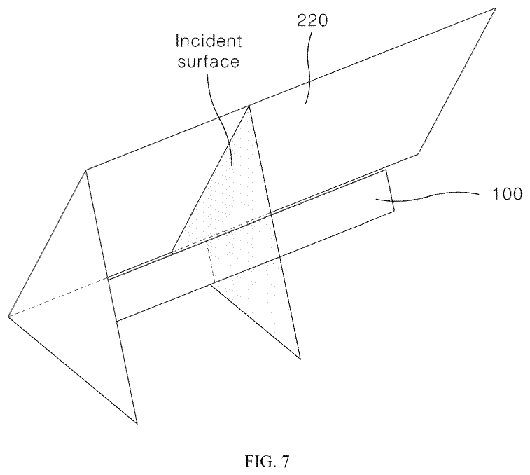

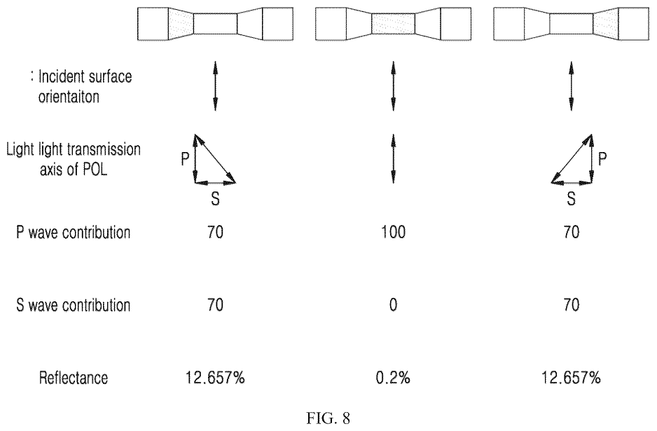

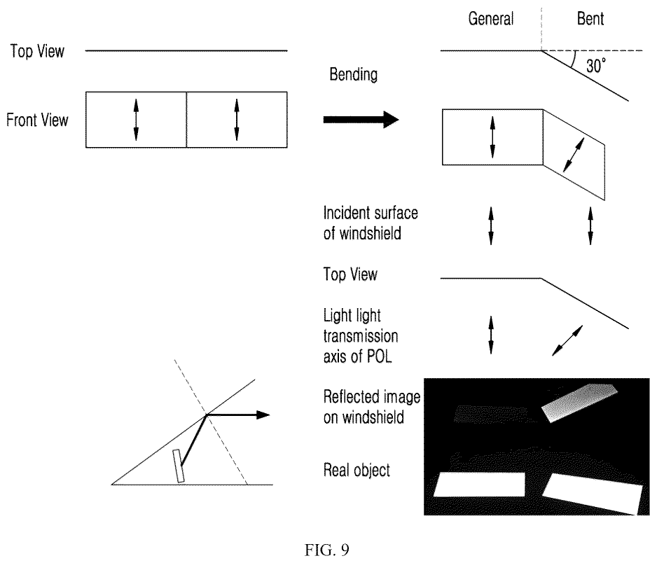

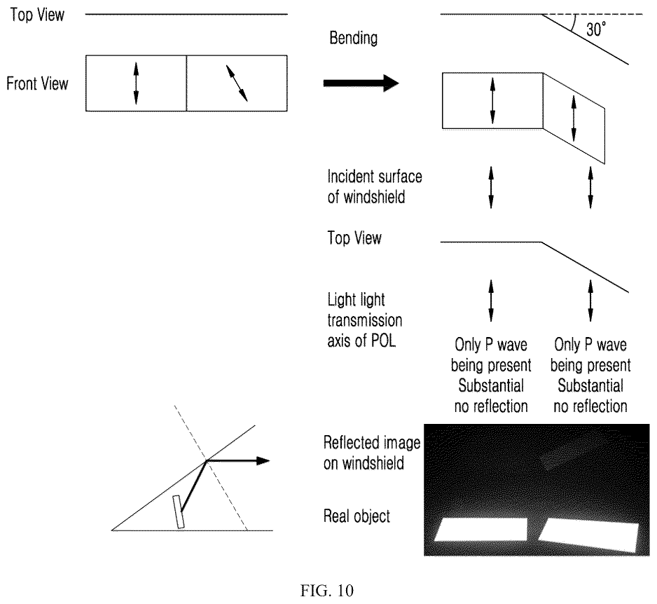

FIG. 7 is a diagram illustrating a display device and an incident surface of a windshield according to an implementation of the present disclosure. FIG. 8 is a diagram illustrating a relationship between a transmission axis and an incident surface of a polarizing layer, a P wave, and an S wave according to an implementation of the present disclosure. FIG. 9 is a diagram illustrating an example in which the displayed image is reflected on a windshield according to the presence of a P wave and a S wave vibrating along a transmission axis of a polarization layer when a display device according to an implementation of the present disclosure is bent. FIG. 10 is a diagram illustrating an example in which a displayed image is not reflected on a windshield according to the presence of only a P wave vibrating along a transmission axis of a polarization layer when a display device according to an implementation of the present disclosure is bent.

Referring to FIG. 7, the windshield 220 is positioned upwardly of the display device 100 according to an implementation of the present disclosure, and the windshield 220 extends toward the driver in an angle inclined with respect to the display device 100.

Accordingly, the windshield 220 has an incident surface to which the displayed image output from the display device 100 is input, and may reflect the display image therefrom based on a direction in which light of the displayed image is incident on the incident surface.

As shown in FIG. 6, the optical adjustment layer POL may be disposed on the display panel 111 in the display device 100. The optical adjustment layer POL may be, for example, a polarizing layer POL.

When a light absorption axis of the polarization layer POL is oriented at 0 degrees (°) (that is, the transmission axis thereof is oriented at 90 degrees (°)), the light emitted from the display panel 111 has a P wave component which vibrates along the incident surface. In this case, the P wave contribution is 100, and the S wave contribution is zero (0)

The display panel 111 may be disposed on the dashboard 210 of the vehicle. The windshield 220 may be disposed on top of the display panel 111.

The orientation of the light transmission axis of the optical adjustment layer POL may be identical with the light incident angle to the windshield 220 when the light output from the display panel 111 is incident on the windshield 220.

Referring to FIG. 8, the display panel 111 may include a general area having a flat surface and a bent area having a bent surface.

A plurality of sub-pixels SP may be disposed in the general area and the bent area, and the plurality of sub-pixels SP may include sub-pixels emitting light of different colors. The plurality of sub-pixels may include at least one of a white sub-pixel, a red sub-pixel, a green sub-pixel, and a blue sub-pixel.

In the display device including the general area and the bent area, the orientations of the transmission axis of the optical adjustment layer POL in the general area and the bent area may be different from each other.

The optical adjustment layer POL may include a first area corresponding to the general area and a second area corresponding to the bent area. The orientation of the light transmission axis of the optical adjustment layer POL in the first area and the second area may have different angles. That is, the first area and the second area have different angles of the light transmission axis of the optical adjustment layer POL to each other

In some alternative scenarios, when the display panel has only the general area, the orientation of the transmission axis of the polarizing layer POL is the same at 90 degrees (°) across the entire general area. However, the bent area of the display panel is bent by 30 degrees (°), the orientation of the transmission axis of the polarizing layer POL in the area corresponding to the bent area is 60 degrees (°) (90 degrees (°)- −30 degrees (°)).

The incident surface is orientated at 90 degrees (°), and the transmission axis in the area of the polarizing layer POL corresponding to the bent area is oriented at 60 degrees (°), so that a portion of light leaks out of the polarizing layer POL and thus the displayed image is reflected on and from the windshield 220 to the viewer.

When the displayed image is reflected on and from the windshield 220, a difference between the reflected image brightness in the general area (front surface) and the reflected image brightness in the bent area (bent surface) may be generated due to the polarization characteristics of the polarization layer POL.

Referring to FIG. 8, when the incident surface of light is oriented in an inclined manner from the vertical direction (90 degrees (°)) to the left side, the transmission axis of the polarization layer POL is oriented such that the transmission axis of the P wave is oriented in the left vertical direction (90 degrees (°)), and the transmission axis of the S wave is oriented in the horizontal direction. In this case, the contribution of the P wave is 70, and the contribution of the S wave is 70, and accordingly, the reflectance is 12.657%.

When the incident surface of light is oriented in an inclined manner from the vertical direction (90 degrees (°)) to the right side, the transmission axis of the polarization layer POL is oriented such that the transmission axis of the P wave is oriented in the right vertical direction (90 degrees (°)), and the transmission axis of the S wave is oriented in the horizontal direction. In this case, the contribution of the P wave is 70, and the contribution of the S wave is 70, and accordingly, the reflectance is 12.657%.

When the incident surface of light is oriented in a vertical direction (90 degrees (°)), the transmission axis of the polarization layer POL is oriented in the vertical direction (90 degrees (°)). In this case, the contribution of the P wave is 100, the contribution of the S wave is 0, and the reflectance is 0.2%.

Referring to FIG. 9, when the bent area (bent surface) is bent by 30 degrees (°) with respect to the general area (front surface), the incident surface of the windshield 220 in each of the areas corresponding to the general and bent areas is oriented in a vertical direction (90 degrees (°)), the transmission axis of the polarizing layer POL in the area corresponding to the general area is oriented in a vertical direction (90 degrees (°)), and the transmission axis of the polarizing layer POL in the area corresponding to the bent area is oriented is in an oblique direction. The oblique direction is oriented, for example, at an angle of 120 degrees (°) (90 degrees+30 degrees).

Accordingly, the light emitted from the general area has the P wave component which is incident on the windshield 220 in the area corresponding to the general area. The light emitted from the bent area has the S wave component which is incident on the windshield 220 in the area corresponding to the bent area. Thus, the displayed image is reflected on and from the windshield 220 in the area corresponding to the bent area.

Referring to FIG. 10, when the bent area (bent surface) is bent by 30 degrees (°) with respect to the general area (front surface), the transmission axis of the optical adjustment layer POL according to an implementation of the present disclosure in each of the area corresponding to the general area and the area corresponding to the bent area is oriented in the vertical direction (90 degrees (°)) such that the only P wave component is incident on the windshield 220 in each of the area corresponding to the general area and the area corresponding to the bent area.

That is, the optical adjustment layer POL may be configured to allow light to be transmitted from the display panel 111 through the first area and the second area corresponding to the general area and the bent area, respectively, and only the P wave is emitted out of each of the first area and the second area.

Accordingly, the displayed image output from the display panel 111 is transmitted from the display panel 111 through the first area and the second area of the optical adjustment layer POL corresponding to the general area and the bent area, respectively such that only the P wave is emitted out of each of the first area and the second area of the optical adjustment layer POL corresponding to the general area and the bent area, respectively, and then is incident on the windshield 220 in each of the first area and the second area of the windshield 220 corresponding to the general area and the bent area. Thus, the image is not reflected on the windshield 220 in each of the first area and the second area of the windshield 220 corresponding to the general area and the bent area. This is shown in FIG. 10.

The angle of the light transmission axis of the optical adjustment layer POL in the second area of the optical adjustment layer POL may be set to a value that adds 90 degrees (°) to an angle at which the display panel 111 is bent in the bent area relative to a horizontal line. For example, when the bent area (bent surface) is bent at 30 degrees (°), the angle of the transmission axis of the optical adjustment layer POL in the second area is set to 120 degrees (°), which is a value obtained by adding 30 degrees (°) to 90 degrees (°).

The angle of the light transmission axis in the second area of the optical adjustment layer POL may be set to a value within a range of 45 degrees (°) to 135 degrees (°).

As described above, in the display device 100 according to an implementation of the present disclosure, based on a structure for changing the orientation of the transmission axis of the optical adjustment layer POL such that the orientation of the incident surface coincides with the orientation of the transmission axis of the optical adjustment layer POL in the area corresponding to the bent area BA, the displayed image may not be reflected on the windshield 220 and thus may not be reflected therefrom to the viewer, that is, the driver.

According to an implementation of the present disclosure, even though the luminance is maintained at 911 nit in the general area (front surface) of the display panel 111 and the luminance is maintained at 631 nit in the bent area (bent surface) of the display panel 111, the luminance of the reflected image on the windshield may be greatly reduced from 178 nit to 29 nit. Accordingly, the displayed image may be hardly reflected on the windshield 220 and thus may not be reflected therefrom to the viewer, that is, the driver.

Moreover, in the display device 100 according to an implementation of the present disclosure, in addition to the above-described implementation, the luminance may be lowered so that, the displayed image may be hardly reflected on the windshield 220 and thus may not be reflected therefrom to the viewer, that is, the driver.

For example, in the general area (front surface or flat surface) of the display panel 111, the luminance may be lowered from 911 nit to 210 nit, and accordingly, the luminance of the reflected image on the windshield may be reduced from 41 nit to 9 nit.

In addition, in the bent area (bent surface) of the display panel 111, the luminance may be lowered from 631 nit to 145 nit, and accordingly, the luminance of the reflected image on the windshield may be lowered from 178 nit to 41 nit.

In one example, in the display device 100 according to an implementation of the present disclosure, the amount of light directed to the windshield 220 may be reduced by changing a light path so as to reduce the reflected image thereon.

For example, in the general area (fronts surface or flat surface) of the display panel 111 according to an implementation of the present disclosure, the luminance may be lowered from 911 nit to 699 nit, and accordingly, the luminance of the reflected image on the windshield may be lowered from 41 nit to 20 nit.

In addition, in the bent area (bent surface) of the display panel 111 according to an implementation of the present disclosure, the luminance may be lowered from 631 nit to 522 nit, and accordingly, the luminance of the reflected image on the windshield may be lowered from 178 nit to 53 nit.

In one example, although not shown in the drawings, the display device 100 according to an implementation of the present disclosure may further include a gate driver, a data driver, and a timing controller.

The display panel 111 according to an implementation of the present disclosure may include a display area where at least one sub-pixel is disposed and a non-display area surrounding the display area.

The display panel 111 according to an implementation of the present disclosure may be connected to a plurality of gate lines (not shown) and data lines (not shown). A plurality of sub-pixels SP may be arranged in a matrix form in the display panel 111.

The gate driver (not shown) may drive the plurality of gate lines (not shown). That is, the gate driver (not shown) may supply a gate signal (scan signal) to the plurality of gate lines (not shown).

The data driver (not shown) may supply data voltage to the plurality of data lines (not shown).

The timing controller (not shown) may control the gate driver (not shown) and the data driver (not shown).

Although not shown, the display device 100 may further include, in addition to the above-described components, a power management circuit that applies power to drive the display panel, a camera for photographing the external environment to the vehicle, and a black box that may store image data captured by the camera.

The display panel 111 according to an implementation of the present disclosure may display an image based on the scan signal transmitted thereto from the gate driver (not shown) through the plurality of gate lines (not shown) and the data voltage transmitted thereto from the data driver (not shown) through the plurality of data lines (not shown).

When the display module is implemented as the liquid crystal display module, the display panel 111 according to an implementation of the present disclosure may include a liquid crystal layer formed between two substrates and may operate in a known mode such as a TN (Twisted Nematic) mode, a VA (Vertical Alignment) mode, a IPS (In Plane Switching) mode, and a FFS (Fringe Field Switching) mode. On the other hand, when the display module is implemented as the organic light-emitting display module, the display panel 111 according to an implementation of the present disclosure may operate in a top emission scheme, a bottom emission scheme, or a dual emission scheme.

The display panel 111 according to an implementation of the present disclosure may have the plurality of sub-pixels arranged in a matrix form. The sub-pixels may include sub-pixels emitting light of different colors, for example, a white sub-pixel, a red sub-pixel, a green sub-pixel, and a blue sub-pixel. An area of each sub-pixel may be defined by the data lines (not shown) and the gate lines (not shown).

One sub-pixel may include a thin-film transistor TFT formed in an area where one data line (not shown) and one gate line (not shown) intersect each other, a light-emitting element such as an organic light-emitting diode that charges the data voltage, and a storage capacitor that is electrically connected to the light-emitting element to maintain the voltage thereof.

The gate driver (not shown) may be controlled by the timing controller (not shown) so as to sequentially output the scan signal to the plurality of gate lines (not shown) arranged in the display panel 111 according to an implementation of the present disclosure, thereby controlling an operation timing of each of the sub-pixels SP.

For example, sequentially outputting the scan signal on a four gate lines (not shown) basis, such as sequentially outputting the scan signal to four gate lines including the first gate line to the fourth gate line and then sequentially outputting the scan signal four gate lines including the fifth gate line to the eighth gate line may be referred to as 4 phase operation. In other words, sequentially outputting the scan signal based on a N gate lines (not shown) basis may be referred to as N-phase operation.

In this regard, the gate driver (not shown) may include one or more gate driving integrated circuits GDIC. Depending on a driving scheme, the gate driver may be located on only one side of the display panel 111 or on each of both opposing sides thereof. Alternatively, the gate driver (not shown) may be built into the bezel area of the display panel 111 and thus may be implemented in a GIP (Gate In Panel) form.

The data driver (not shown) receives sub-image data from the timing controller (not shown) and converts the received sub-image data into analog data voltage. Then, the data driver outputs the data voltage to each data line (not shown) in accordance with a timing at which the scan signal is applied through the gate line (not shown). Thus, each sub-pixel SP connected to the data line (not shown) displays a light-emission signal with brightness corresponding to the data voltage.

Likewise, the data driver (not shown) may include one or more source driving integrated circuits SDIC. The source driving integrated circuit SDIC may be connected to a bonding pad of the display panel 111 using a TAB (Tape Automated Bonding) scheme or a COG (Chip On Glass) scheme, or may be disposed directly on the display panel 111.

In some cases, each source driving integrated circuit SDIC may be integrated into the display panel 111. Furthermore, each source driving integrated circuit SDIC may be implemented in a COF (Chip On Film) manner. In this case, each source driving integrated circuit SDIC may be mounted on a circuit film and may be electrically connected to the data line (not shown) of the display panel 111 through the circuit film.

The timing controller (not shown) supplies various control signals to the gate driver (not shown) and the data driver (not shown), and controls the operations of the gate driver (not shown) and the data driver (not shown). In other words, the timing controller (not shown) controls the gate driver (not shown) to output the scan signal according to a timing implemented in each frame. On the other hand, the timing controller (not shown) transmits the image data DATA transmitted thereto from the camera or the image data DATA transmitted thereto through the black box to the data driver (not shown).

In this regard, the timing controller (not shown) may receive, from the host system, the image data DATA and various timing signals which includes a vertical synchronization signal Vsync, a horizontal synchronization signal Hsync, a data enable signal DE, a main clock MCLK, etc.

The host system may include one or more of a TV Television system, a set-top box, a navigation system, a personal computer (PC), a home theater system, a mobile device, a wearable device, a camera 160, and a black box 170. In this regard, an example in which the timing controller (not shown) receives the image data DATA through the camera that may photograph the external environment to the vehicle or the black box that may store therein the image data DATA taken from the camera will be described below.

Accordingly, the timing controller (not shown) generates a control signal using the various timing signals received from the camera or the black box and transmits the control signal to the gate driver (not shown) and the data driver (not shown).

For example, the timing controller (not shown) outputs various gate control signals including a gate start pulse GSP, a gate clock GCLK, and a gate output enable signal GOE, etc. to control the gate driver (not shown). In this regard, the gate start pulse GSP controls a timing at which one or more gate driving integrated circuits GDIC constituting a gate driving circuit (not shown) start operating. Furthermore, the gate clock GCLK is a clock signal commonly input to one or more gate driving integrated circuits GDIC, and controls a shift timing of the scan signal. Furthermore, the gate output enable signal GOE specifies timing information of one or more gate driving integrated circuits GDIC.

Furthermore, the timing controller (not shown) outputs various data control signals including a source start pulse SSP, a source sampling clock SCLK, and a source output enable signal SOE, etc. to control the data driver (not shown). In this regard, the source start pulse SSP controls a timing at which one or more source driving integrated circuits SDICs constituting the data driver (not shown) start sampling data. The source sampling clock SCLK is a clock signal that controls a timing at which the source driving integrated circuit SDIC samples the data. The source output enable signal SOE controls an output timing of the data driver (not shown).

This display device 100 may include the power management circuit (not shown) that supplies various voltages or currents to the display panel 111, the gate driver (not shown), the data driver (not shown), or controls the various voltages or currents to be supplied thereto. The power management circuit adjusts a direct current input voltage to generate power required to drive the display panel 111, the gate driver (not shown), and the data driver (not shown).

The display device 100 according to an implementation of the present disclosure refers to a display device having flexibility, and may include a bendable display device, a rollable display device that may be rolled, an unbreakable display device that does not break, and a foldable display device that can be folded.

The driver integrated circuit may be implemented as a TFT (thin film transistor) in the non-display area NA. This driver integrated circuit may be referred to as a GIP (gate-in-panel) circuit. The GIP circuit includes a gate driver of a GIP structure, wherein the gate driver is implemented as a bottom gate type thin-film transistor (BG-T), and a source and drain metal film of a bridge line extends so as to connected to a drain electrode of the BG thin-film transistor.

Moreover, some components, such as the data driver IC may be mounted on a separate printed circuit board, or may be coupled to a connection interface (pads/bumps, pins, etc.) disposed in the non-display area NA using a circuit film such as FPCB (flexible printed circuit board), COF (chip-on-film), or TCP (tape-carrier-package). The non-display area NA may be bent along with the connection interface, so that the printed circuit (COF, PCB, etc.) may be disposed on the rear surface (or the back surface) of the display device 100.

The display device 100 according to the present disclosure may include various additional components for generating various signals or driving the pixel PX in the display area. The additional components to drive the pixel may include an inverter circuit, a multiplexer, an electrostatic discharge circuit. The display device 100 according to the present disclosure may include additional components related to functions other than the function of driving the pixel. For example, the display device 100 according to the present disclosure may include additional components that provide a touch sensing function, a user authentication function such as fingerprint recognition, a multi-level pressure sensing function, and a tactile feedback function. The above-mentioned additional components may be disposed in an external circuit connected to the non-display area NA and/or the connection interface.

According to the present disclosure, several portions of the display device 100 may be bent along a bendable line. The bendable line may extend transversely, longitudinally, or diagonally. Accordingly, the display device 100 according to an implementation of the present disclosure may be bent in a combination of the transverse, longitudinal and diagonal directions based on a required design.

According to the present disclosure, one or more corner edges of the display device 100 may be bent along the bendable line so as to be away from a central portion. The bendable line may be disposed closer to the edge of the display device 100, but may extend across the central portion, or may extend diagonally from one or more corners of the display device 100. This structure may enable the display device 100 to be implemented as a foldable display device or a display device in which an image is displayed from each of both folded surfaces facing each other.

Since one or more portions of the display device 100 may be bent, the display device 100 according to the present disclosure may be divided into a substantially flat area and a curved area. One portion of the display device 100 may be referred to as a substantially flat area. One portion of the display device 100 may be bent at a predetermined angle, and this portion may be referred to as a bent area or a curvature area. The curvature area includes a bent section that is actually bent at a predetermined curvature radius.

The term “substantially flat” means that the substantially flat area includes a portion which is not perfectly flat. For example, a concave central portion and a convex central portion may belong to the substantially flat area in some implementations. One or more bent sections may be present next to the concave central portion or the convex central portion, and are bent inwardly or outwardly at an angle relative to a bending axis along the bendable line. The curvature radius of the curvature area is smaller than that of the flat area. In other words, the term “substantially flat area” means a portion with a smaller curvature than that of a portion adjacent thereto.

Depending on a position of the bendable line, a portion on one side of the bendable line is positioned toward the center of the display device 100, while a portion on the other side of the bendable line is positioned toward the edge of the display device 100. A portion positioned toward the center of the display device 100 may be referred to as a central portion, and a portion positioned toward the edge of the display device 100 may be referred to as an edge portion. The central portion of the display device 100 may be substantially flat, and the edge portion may be a bent section. However, this is not always true. The substantially flat area may also be disposed in the edge portion. Further, in some shapes of the display device 100, the bent section may be disposed between two substantially flat areas.

When the non-display area NA is bent, the non-display area NA may be invisible or minimally visible to a viewer in front of the display device 100. A portion of the non-display area NA visible to the view in front of the display device 100 may be screened with a bezel. The bezel may be formed as a stand-alone structure, or as a housing or another suitable element. A portion of the non-display area NA visible to the view in front of the display device 100 may be hidden under an opaque mask layer such as a black ink layer made of black ink (e.g., a polymer filled with carbon black). Such an opaque mask layer may be disposed on various layers (e.g., a touch sensor layer, a polarization layer, a cover layer, and the like) included in the display device 100.

In some implementations, the bent section of the display device 100 may include a display area capable of displaying an image. That is, the bendable line may be disposed in the display area so that at least some of pixels of the display area are included in the bent section.

The display device according to various aspects and implementations of the present disclosure may be described as follows.

One aspect of the present disclosure provides a display device comprising: a display panel including a general area having a flat surface and a bent area having a bent surface; and an optical adjustment layer disposed on the display panel, wherein the optical adjustment layer includes a first area corresponding to the general area and a second area corresponding to the bent area, wherein an angle of a light transmission axis of the optical adjustment layer in the first area is different from an angle of a light transmission axis of the optical adjustment layer in the second area.

In accordance with some implementations of the present disclosure, the optical adjustment layer is configured to allow light to be transmitted from the display panel through the first area and the second area, and only a P wave component exists in each of the first area and the second area.

In accordance with some implementations of the present disclosure, the angle of the light transmission axis in the second area of the optical adjustment layer is set to a value that add 90 degrees (°) to an angle at which the display panel is bent in the bent area relative to a horizontal line.

In accordance with some implementations of the present disclosure, the angle of the light transmission axis in the second area of the optical adjustment layer is set to a value within a range of 45 degrees (°) to 135 degrees (°).

In accordance with some implementations of the present disclosure, the display panel is disposed on a dashboard of a vehicle, wherein a windshield of the vehicle is disposed in an upper direction of the display panel, wherein the angle of the light transmission axis of the optical adjustment layer is same as the light incident angle of the windshield when the light output from the display panel is incident on the windshield.

In accordance with some implementations of the present disclosure, the display device further comprises: a first adhesive layer disposed on the optical adjustment layer; a light control film disposed on the first adhesive layer; a second adhesive layer disposed on of the light control film; and a cover member disposed on the second adhesive layer.

In accordance with some implementations of the present disclosure, the display device further comprises: a black matrix disposed on the second adhesive layer; and a cover member disposed on the black matrix.

In accordance with some implementations of the present disclosure, the black matrix includes a plurality of holes defined therein, and is formed by filling a black pigment therein through the plurality of holes.

In accordance with some implementations of the present disclosure, a plurality of sub-pixels are disposed in each of the general area and the bent area of the display panel, wherein the plurality of sub-pixels emit light of different colors.

In accordance with some implementations of the present disclosure, the plurality of sub-pixels include at least one of a white sub-pixel, a red sub-pixel, a green sub-pixel, and a blue sub-pixel.

In accordance with some implementations of the present disclosure, the display device further comprises: a back plate disposed below the display panel; a metal plate disposed below the back plate; an adhesive tape disposed below the metal plate; and a guide holder disposed below the adhesive tape.

In accordance with some implementations of the present disclosure, a set frame is disposed below the guide holder, and the guide holder is fastened to the set frame by screw fastening.

In accordance with some implementations of the present disclosure, the guide holder includes a source printed circuit board (PCB) received therein, wherein the source PCB is electrically connected to the display panel through a flexible printed circuit board.

Although implementations of the present disclosure have been described with reference to the accompanying drawings, the present disclosure is not limited to the above implementations, but may be implemented in various different forms. A person skilled in the art may appreciate that the present disclosure may be practiced in other concrete forms without changing the technical spirit or essential characteristics of the present disclosure. Therefore, it should be appreciated that the implementations as described above is not restrictive but illustrative in all respects.

What is claimed is:

1. A display device comprising:
a display panel including a general area having a flat surface and a bent area having a bent surface; and
an optical adjustment layer disposed on the display panel,
wherein the optical adjustment layer includes a first area corresponding to the general area and a second area corresponding to the bent area, and
wherein an angle of a light transmission axis of the optical adjustment layer in the first area is different from an angle of a light transmission axis of the optical adjustment layer in the second area.

2. The display device of claim 1, wherein the optical adjustment layer is configured to allow light to be transmitted from the display panel through the first area and the second area, and only a P wave component exists in each of the first area and the second area.

3. The display device of claim 1, wherein the angle of the light transmission axis in the second area of the optical adjustment layer is set to a value that adds 90 degrees (°) to an angle at which the display panel is bent in the bent area relative to a horizontal line.

4. The display device of claim 1, wherein the angle of the light transmission axis in the second area of the optical adjustment layer is set to a value within a range of 45 degrees (°) to 135 degrees (°).

5. The display device of claim 1, wherein the display panel is disposed on a dashboard of a vehicle,
wherein a windshield of the vehicle is disposed in an upper direction of the display panel,
wherein the angle of the light transmission axis of the optical adjustment layer is same as the light incident angle of the windshield when the light output from the display panel is incident on the windshield.

6. The display device of claim 1, wherein the display device further comprises:
a first adhesive layer disposed on the optical adjustment layer;
a light control film disposed on the first adhesive layer;
a second adhesive layer disposed on the light control film; and
a cover member disposed on the second adhesive layer.

7. The display device of claim 6, wherein the display device further comprises:
a black matrix disposed on the second adhesive layer; and
a cover member disposed on the black matrix.

8. The display device of claim 7, wherein the black matrix includes a plurality of holes defined therein, and is formed by filling a black pigment therein through the plurality of holes.

9. The display device of claim 1, wherein a plurality of sub-pixels are disposed in each of the general area and the bent area of the display panel,
wherein the plurality of sub-pixels are configured to emit light of different colors.

10. The display device of claim 9, wherein the plurality of sub-pixels include at least one of a white sub-pixel, a red sub-pixel, a green sub-pixel, and a blue sub-pixel.

11. The display device of claim 1, wherein the display device further comprises:
a back plate disposed below the display panel;
a metal plate disposed below the back plate;
an adhesive tape disposed below the metal plate; and
a guide holder disposed below the adhesive tape.

12. The display device of claim 11, wherein a set frame is disposed below the guide holder, and the guide holder is fastened to the set frame by screw fastening.

13. The display device of claim 11, wherein the guide holder includes a source printed circuit board (PCB) received therein,
wherein the source PCB is electrically connected to the display panel through a flexible printed circuit board.
